(19) United States
(12) Patent Application Publication
(10) Pub. No.: US 2023/0386798 A1
(43) Pub. Date: Nov. 30, 2023

(54) SUBSTRATE PROCESSING APPARATUS AND METHOD FOR ALIGNING RING MEMBER

(71) Applicant: Tokyo Electron Limited, Tokyo (JP)

(72) Inventors: Mohd Fairuz BIN BUDIMAN, Miyagi (JP); Shinya MORIKITA, Miyagi (JP); Masafumi URAKAWA, Boise, ID (US)

(73) Assignee: Tokyo Electron Limited, Tokyo (JP)

(21) Appl. No.: 18/199,401

(22) Filed: May 19, 2023

(30) Foreign Application Priority Data
May 26, 2022 (JP) 2022-086282

(51) Int. Cl. H01J 37/32

(52) U.S. Cl. CPC H01J 37/32642; H01J 37/32715; H01J 37/3244

(57) ABSTRACT

There is provided a substrate processing apparatus comprising: a plasma processing chamber; a support accommodated in the plasma processing chamber; an inner edge ring provided around a substrate; an outer edge ring provided around the inner edge ring, the outer edge ring having an inner peripheral portion overlapping an outer peripheral portion of the inner edge ring when viewed from above and having a first alignment portion; an outer edge ring electrostatic chuck disposed at a position of the support, the position facing the outer edge ring; and a lifter configured to move the inner edge ring and/or the outer edge ring up and down. The inner edge ring is configured to be aligned with the outer edge ring by the first alignment portion in a state in which the outer edge ring electrostatic chuck is driven and the outer edge ring is attracted.

### CROSS-REFERENCE TO RELATED APPLICATION

This application claims priority to Japanese Patent Application No. 2022-086282, filed on May 26, 2022, the entire contents of which are incorporated herein by reference.

### TECHNICAL FIELD

The present disclosure relates to a substrate processing apparatus and a method for aligning a ring member.

### BACKGROUND

For example, Patent Document 1 proposes a plasma processing apparatus in which a wafer is placed on a wafer placing surface of a placing table, and a first ring and a second ring are placed on a ring placing surface of the placing table. The plasma processing apparatus includes a driving mechanism capable of driving lifter pins to move up and down, and the lifter pins move at least one of the first ring and the second ring up and down to transfer.

### PRIOR ART DOCUMENTS

### Patent Documents

Patent Document 1: Japanese Laid-open Patent Publication No. 2020-113603

### SUMMARY

The present disclosure provides a technique capable of accurately aligning a ring member when replacing the ring member in a substrate processing apparatus.

According to an aspect of the present disclosure, there is provided a substrate processing apparatus comprising: a plasma processing chamber; a support accommodated in the plasma processing chamber; an inner edge ring provided around a substrate; an outer edge ring provided around the inner edge ring, the outer edge ring having an inner peripheral portion overlapping an outer peripheral portion of the inner edge ring when viewed from above and having a first alignment portion; an outer edge ring electrostatic chuck disposed at a position of the support, the position facing the outer edge ring; and a lifter configured to move the inner edge ring and/or the outer edge ring up and down. The inner edge ring is configured to be aligned with the outer edge ring by the first alignment portion in a state in which the outer edge ring electrostatic chuck is driven and the outer edge ring is attracted.

### BRIEF DESCRIPTION OF THE DRAWINGS

The objects and features of the present disclosure will become apparent from the following description of embodiments given in conjunction with the accompanying drawings, in which:

FIG. 1 is a cross-sectional view showing an example of a plasma processing apparatus according to an embodiment;

FIG. 2 is a cross-sectional view showing an example of an edge ring and an elevating part according to the embodiment;

FIGS. 3A and 3B are diagrams explaining a problem when replacing the edge ring according to a reference example;

FIG. 4 is a flow chart showing an example of a transfer method according to the embodiment;

FIGS. 5A to 5E are diagrams explaining the transfer method according to the embodiment;

FIGS. 6A to 6E are diagrams explaining the transfer method (continued from FIGS. 5A to 5E) according to the embodiment;

FIGS. 7A to 7E are diagrams explaining another example of the transfer method according to the embodiment;

FIGS. 8A to 8E are diagrams explaining another example of the transfer method according to the embodiment;

FIGS. 9A to 9D are diagrams showing modified examples 1 to 4 of the edge ring and its peripheral structure according to the embodiment;

FIGS. 10A and 10B are diagrams showing modified examples 5 and 6 of the edge ring and its peripheral structure according to the embodiment;

FIGS. 11A and 11B are diagrams showing an example of a positioning structure using pins according to the embodiment; and

FIG. 12 is a diagram showing an example of a substrate processing system according to the embodiment.

### DETAILED DESCRIPTION

Hereinafter, embodiments for carrying out the present disclosure will be described with reference to the accompanying drawings. In each drawing, the same components are designated by the same reference numerals, and redundant description thereof may be omitted.

In this specification, parallel, right angle, orthogonal, horizontal, vertical, up and down, and left and right directions are allowed to deviate to the extent that the effect of the embodiments is not impaired. The shape of corners is not limited to right angles and may be arcuate. The terms parallel, right angle, orthogonal, horizontal, vertical, circular, and coincident may include substantially parallel, substantially right angle, substantially orthogonal, substantially horizontal, substantially vertical, substantially circular, and substantially coincident, respectively.

[Plasma Processing Apparatus]

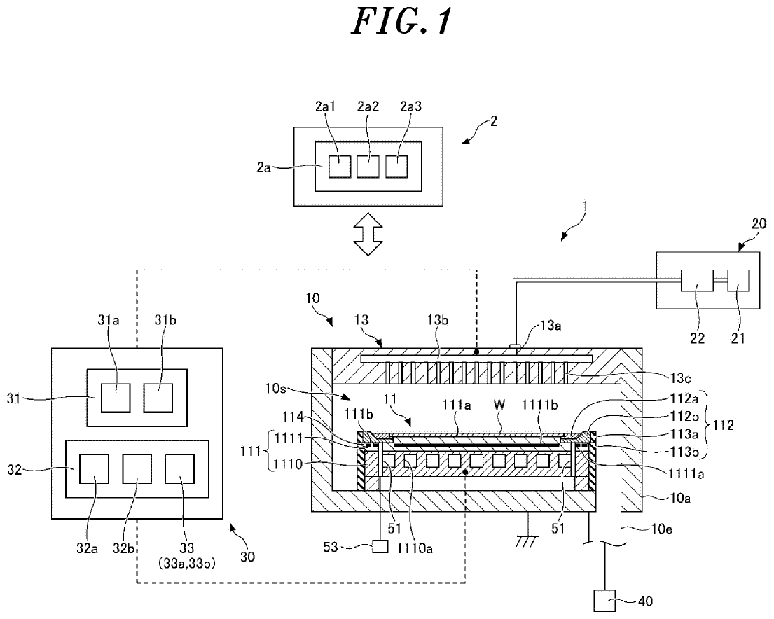

A configuration example of a plasma processing system is described below. FIG. 1 is a diagram explaining a configuration example of a capacitively coupled plasma processing apparatus 1. The plasma processing apparatus 1 is an example of a substrate processing apparatus in which a ring member such as an edge ring is arranged.

The plasma processing system includes the capacitively coupled plasma processing apparatus 1 and a control device 2. The capacitively coupled plasma processing apparatus 1 includes a plasma processing chamber 10, a gas supply 20, a power supply 30, and an exhaust system 40. The plasma processing apparatus 1 further includes a substrate support 11 (supporting table) and a gas introducing part. The gas introducing part is configured to introduce at least one processing gas into the plasma processing chamber 10. The gas introducing part includes a shower head 13. The substrate support 11 is disposed in the plasma processing chamber 10. The shower head 13 is disposed above the substrate support 11. In an embodiment, the shower head 13 forms at least a portion of a ceiling of the plasma processing chamber 10. The plasma processing chamber 10 has a plasma processing space defined by the shower head 13, a side wall 10a of the plasma processing chamber 10, and the substrate support 11. The plasma processing chamber 10 has at least one gas supply port for supplying at least one processing gas to the plasma processing space 10s, and at least one gas exhaust port for exhausting gas from the plasma processing space 10s. The plasma processing chamber 10 is grounded. The shower head 13 and the substrate support 11 are electrically insulated from the housing of the plasma processing chamber 10.

The substrate support 11 includes a main body 111 and a ring assembly 112. The main body 111 has a central region 111a for supporting a substrate W and an annular region 111b for supporting the ring assembly 112. A wafer is an example of the substrate W. The annular region 111b of the main body 111 surrounds the central region 111a of the main body 111 in plan view. The substrate W is disposed on the central region 111a of the main body 111, and the ring assembly 112 is disposed on the annular region 111b of the main body 111 so as to surround the substrate W on the central region 111a of the main body 111. Therefore, the central region 111a is also referred to as a substrate supporting surface for supporting the substrate W, and the annular region 111b is also referred to as a ring supporting surface for supporting the ring assembly 112.

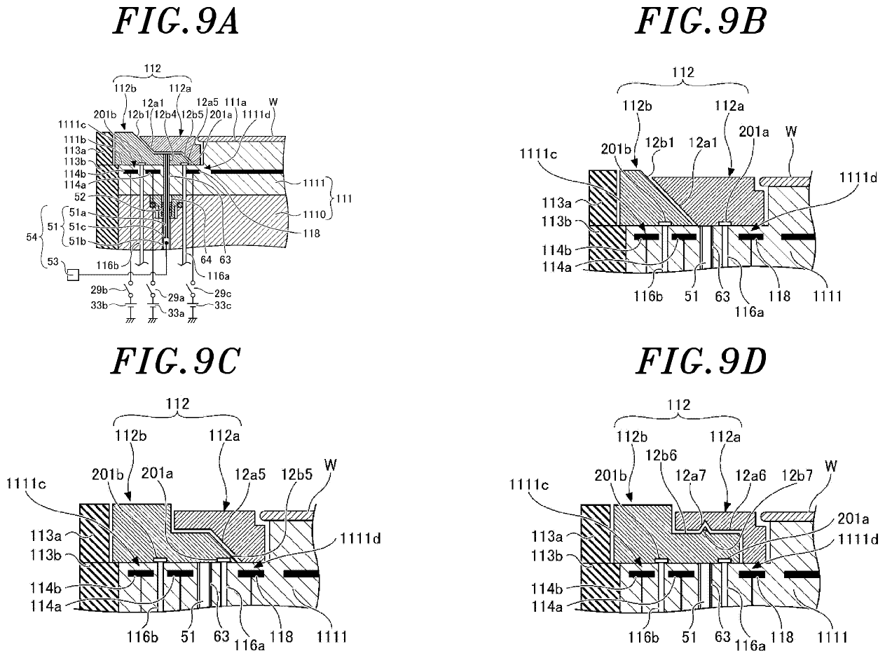

In the embodiment, the main body 111 includes a base 1110 and an electrostatic chuck 1111. The base 1110 includes a conductive member. The conductive member of the base 1110 can function as a lower electrode. The electrostatic chuck 1111 is disposed on the base 1110. The electrostatic chuck 1111 includes a ceramic member 1111a, and a first electrostatic electrode 114 and a third electrostatic electrode 1111b disposed in the ceramic member 1111a. The electrostatic chuck 1111 may include a second electrostatic electrode 118 (see FIGS. 9A to 9D), which will be described later. The first electrostatic electrode 114 is disposed at a position corresponding to the ring assembly 112 in the electrostatic chuck 1111. The third electrostatic electrode 1111b is disposed at a position corresponding to the substrate W in the electrostatic chuck 1111.

The ceramic member 1111a has the central region 111a. In the embodiment, the ceramic member 1111a also has the annular region 111b. Other members surrounding the electrostatic chuck 1111, such as an annular electrostatic chuck or an annular insulating member, may have the annular region 111b. In this case, the ring assembly 112 may be disposed on the annular electrostatic chuck or the annular insulating member, or may be disposed on both the electrostatic chuck 1111 and the annular insulating member. Further, at least one RF/DC electrode coupled to a radio frequency (RF) power supply 31 and/or a direct current (DC) power supply 32, which will be described later, may be disposed in the ceramic member 1111a. In this case, at least one RF/DC electrode functions as the lower electrode. When a bias RF signal and/or a DC signal, which will be described later, is applied to at least one RF/DC electrode, the RF/DC electrode is also referred to as a bias electrode. The conductive member of the base 1110 and at least one RF/DC electrode may function as a plurality of lower electrodes. Further, the third electrostatic electrode 1111b may function as the lower electrode. Accordingly, the substrate support 11 includes at least one lower electrode.

The ring assembly 112 includes one or more annular members. In the embodiment, the one or more annular members include one or more edge rings and at least one cover ring. The edge ring is made of a conductive material or an insulating material, and the cover ring is made of an insulating material.

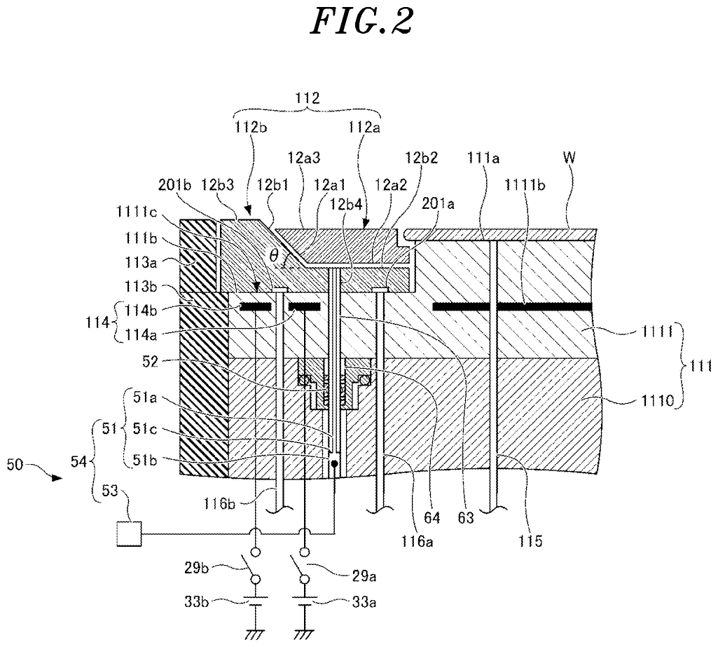

In the example of FIG. 1, the ring assembly 112 includes an inner edge ring 112a, an outer edge ring 112b, a cover ring 113a, and an insulating member 113b. The inner edge ring 112a, the outer edge ring 112b, the cover ring 113a, and the insulating member 113b are annular and concentrically formed. The ring assembly 112 will be described later with reference to FIG. 2.

The annular region 111b of the main body 111 is provided with a heat transfer gas supply having gas supply paths 116a and 116b for supplying a backside gas for heat transfer between a rear surface of the ring assembly 112 (outer edge ring 112b) and the annular region 111b. A groove 201a of 50 μm to hundreds of μm is annularly formed on a rear surface (lower surface) of the outer edge ring 112b corresponding to the gas supply path 116a. The gas supply path 116b is disposed on an outer side of the gas supply path 116a. A groove 201b of 50 μm to hundreds of μm is annularly formed on the rear surface of the outer edge ring 112b corresponding to the gas supply path 116b. The backside gas is supplied to the gas supply paths 116a and 116b from a gas supply source (not shown). The gas supply paths 116a and 116b are also collectively referred to as a gas supply path 116. The two gas supply paths 116a and 116b need not be disposed, only one of them may be disposed. For example, He gas can be used as the backside gas. In the present disclosure, a backside gas for heat transfer is supplied between the rear surface (grooves 201a and 201b) of the outer edge ring 112b and the annular region 111b. However, the heat transfer gas supply having the gas supply path 116 is not limited thereto, and the backside gas for heat transfer may be supplied between a rear surface of at least one of the inner edge ring 112a and the outer edge ring 112b and the annular region 111b. A heat transfer sheet may be provided at least partially between the rear surface of the outer edge ring 112b and the annular region 111b (ring supporting surface), which is an upper surface of the electrostatic chuck 1111.

Further, the substrate support 11 may include a temperature control module configured to control at least one of the electrostatic chuck 1111, the ring assembly 112, and the substrate to a target temperature. The temperature control module may include a heater, a heat transfer medium, a channel 1110a, or combinations thereof. A heat transfer fluid, such as brine or gas, flows through the channel 1110a. In the embodiment, the channel 1110a is formed in the base 1110 and one or more heaters are disposed in the ceramic member 1111a of the electrostatic chuck 1111. Further, the substrate support 11 may include a heat transfer gas supply (see the gas supply path 115 in FIG. 2) configured to supply a heat transfer gas to the gap between a rear surface of the substrate W and the central region 111a.

The shower head 13 is configured to introduce at least one processing gas from the gas supply 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s through the plurality of gas introduction ports 13c. Further, the shower head 13 includes at least one upper electrode. In addition to the shower head 13, the gas introducing part may include one or more side gas injectors (SGI) attached to one or more openings formed in the side wall 10a.

The gas supply 20 may include at least one gas source 21 and at least one flow controller 22. In the embodiment, the gas supply 20 is configured to supply at least one processing gas from each gas source 21 through the corresponding flow controller 22 to the shower head 13. Each flow controller 22 may include, for example, a mass flow controller or a pressure controlled flow controller. Further, the gas supply 20 may include one or more flow modulation devices that modulate or pulse the flow of at least one processing gas.

The power supply 30 includes the RF power supply 31 coupled to the plasma processing chamber 10 via at least one impedance matching circuit. The RF power supply 31 is configured to supply at least one RF signal (RF power) to at least one lower electrode and/or at least one upper electrode. Thereby, a plasma is generated from at least one processing gas supplied to the plasma processing space 10s. Therefore, the RF power supply 31 may function as at least part of a plasma generator configured to generate a plasma from one or more processing gases in the plasma processing chamber 10. Further, by supplying a bias RF signal to at least one lower electrode, a bias potential is generated in the substrate W, and ionic components in the generated plasma may be drawn into the substrate W.

In the embodiment, the RF power supply 31 includes a first RF generator 31a and a second RF generator 31b. The first RF generator 31a is coupled to at least one lower electrode and/or at least one upper electrode via at least one impedance matching circuit and is configured to generate a source RF signal (source RF power) for plasma generation. In the embodiment, the source RF signal has a frequency within a range of 10 MHz to 150 MHz. In the embodiment, the first RF generator 31a may be configured to generate a plurality of source RF signals having different frequencies. The generated one or more source RF signals are provided to at least one lower electrode and/or at least one upper electrode.

The second RF generator 31b is coupled to at least one lower electrode via at least one impedance matching circuit and is configured to generate a bias RF signal (bias RF power). A frequency of the bias RF signal may be the same as or different from a frequency of the source RF signal. In the embodiment, the bias RF signal has a frequency that is lower than a frequency of the source RF signal. In the embodiment, the bias RF signal has a frequency within a range of 100 kHz to 60 MHz. In the embodiment, the second RF generator 31b may be configured to generate a plurality of bias RF signals having different frequencies. The generated one or more bias RF signals are provided to at least one lower electrode. Further, in various embodiments, at least one of the source RF signal and the bias RF signal may be pulsed.

Further, the power supply 30 may include the DC power supply 32 coupled to the plasma processing chamber 10. The DC power supply 32 includes a first DC generator 32a, a second DC generator 32b, and a third DC generator 33. In the embodiment, the first DC generator 32a is connected to at least one lower electrode and is configured to generate a first DC signal. The generated first DC signal is applied to at least one lower electrode. In the embodiment, the second DC generator 32b is connected to at least one upper electrode and is configured to generate a second DC signal. The generated second DC signal is applied to at least one upper electrode. In the embodiment, the third DC generator 33 is connected to at least the first electrostatic electrode 114 and is configured to generate a third DC signal. The generated third DC signal is applied to at least the first electrostatic electrode 114, thereby applying a DC voltage to the first electrostatic electrode 114. The generated third DC signal may be applied to the second electrostatic electrode 118. The first electrostatic electrode 114 may be provided in the same dielectric (the ceramic member 1111a in FIG. 1) as a dielectric in which the third electrostatic electrode 1111b is disposed, or may be provided in a dielectric different from a dielectric in which the third electrostatic electrode 1111b is disposed by dividing the ceramic member 1111a into the central region 111a and the annular region 111b.

In various embodiments, at least one of the first and second DC signals may be pulsed. In this case, a sequence of voltage pulses is applied to at least one lower electrode and/or at least one upper electrode. The voltage pulses may have rectangular, trapezoidal, triangular, or combinations thereof pulse waveforms. In the embodiment, a waveform generator for generating a sequence of voltage pulses from a DC signal is connected between the first DC generator 32a and at least one lower electrode. Therefore, the first DC generator 32a and the waveform generator constitute a voltage pulse generator. When the second DC generator 32b and the waveform generator constitute the voltage pulse generator, the voltage pulse generator is connected to at least one upper electrode. The voltage pulse may have a positive polarity or a negative polarity. Further, the sequence of voltage pulses may include one or more positive voltage pulses and one or more negative voltage pulses in one cycle. The first and second DC generators 32a and 32b may be provided in addition to the RF power supply 31, or the first DC generator 32a may be provided instead of the second RF generator 31b.

The exhaust system 40 may be connected, for example, to a gas exhaust port 10e provided at a bottom of the plasma processing chamber 10. The exhaust system 40 may include a pressure regulating valve and a vacuum pump. The pressure regulating valve adjusts a pressure in the plasma processing space 10s, and the interior of the plasma processing space becomes a vacuum (reduced pressure) state. The vacuum pump may include a turbomolecular pump, a dry pump, or a combination thereof.

The control device 2 processes computer-executable instructions that cause the plasma processing apparatus 1 to perform various steps described in the present disclosure. The control device 2 may be configured to control each component of the plasma processing apparatus 1 to perform various steps described herein. In the embodiment, part or all of the control device 2 may be included in the plasma processing apparatus 1. The control device 2 may include a processor 2a1, a storage 2a2, and a communication interface 2a3. The control device 2 is implemented, for example, by a computer 2a. The processor 2a1 may be configured to perform various control operations by reading a program from the storage 2a2 and executing the read program. This program may be stored in the storage 2a2 in advance or may be acquired from a medium when necessary. The acquired program is stored in the storage 2a2 and read from the storage 2a2 and executed by the processor 2a1. The medium may be various storage media readable by the computer 2a, or a communication line connected to the communication interface 2a3. The processor 2a1 may be a central processing unit (CPU). The storage 2a2 may include a random access memory (RAM), a read only memory (ROM), a hard disk drive (HDD), a solid state drive (SSD), or combinations thereof. The communication interface 2a3 may communicate with the plasma processing apparatus 1 via a communication line such as a local area network (LAN).

[Transfer of Edge Ring]

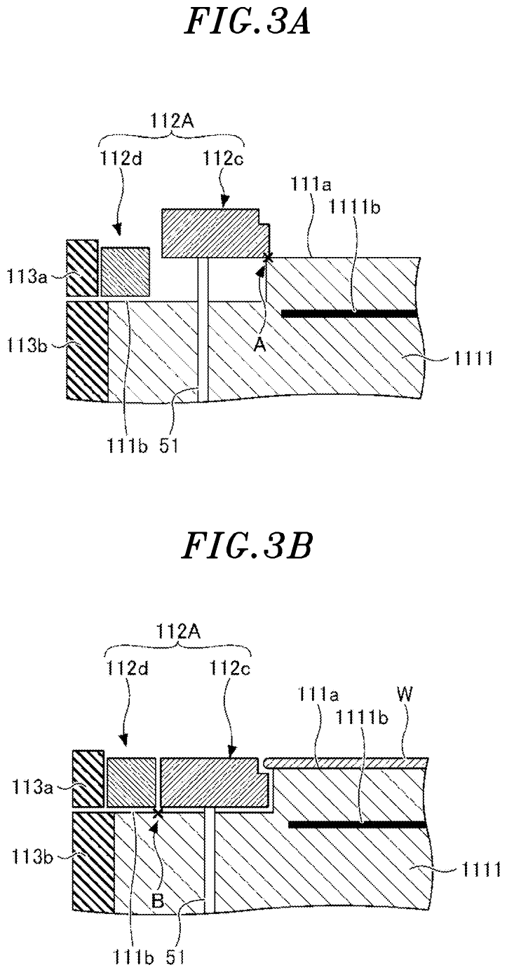

FIG. 2 is a cross-sectional view showing an example of the ring assembly 112 including the edge ring and an elevating part 50 according to the embodiment. FIGS. 3A and 3B are diagrams explaining a problem when replacing the edge ring according to a reference example.

A plurality of ring members including the edge ring are disposed in the plasma processing apparatus 1. An example of the ring members includes edge rings (the inner edge ring 112a and the outer edge ring 112b) disposed on a radially outer side of the substrate W to improve the in-plane uniformity of the plasma processing of the substrate W, and the cover ring 113a. The ring member must be replaced when the wear exceeds an acceptable range. For example, when the edge ring wears, the thickness of the sheath on the edge ring changes, the angle of incidence of the ions on the substrate W changes, and the processing on the substrate W changes, so the ring member must be replaced. If the intervals for replacing the ring members (chamber maintenance cycle) are shortened, the operation rate of the plasma processing apparatus 1 is decreased and the productivity of the plasma processing apparatus 1 is decreased.

Therefore, by providing the elevating part 50 capable of automatically transferring the ring members, the ring members can be replaced without exposing the plasma processing chamber 10 to the atmosphere, thereby shortening the chamber maintenance cycle and improving the productivity of the plasma processing apparatus 1.

The ring assembly 112 includes the edge ring divided into the inner edge ring 112a and the outer edge ring 112b. In the transfer method according to one embodiment, an example is described in which the inner edge ring 112a, which wears faster than the outer edge ring 112b among the ring members, is transferred by the elevating part 50 and replaced with the inner edge ring 112a for replacement. The inner edge ring 112a for replacement includes new and relatively new. The outer edge ring 112b is fixed and is not transferred by the elevating part 50. However, the present disclosure is not limited thereto and the outer edge ring 112b may be transferred or both the inner edge ring 112a and the outer edge ring 112b may be transferred.

With reference to FIGS. 3A and 3B according to the reference example, a problem in replacing the edge ring 112A using the elevating part is described. The edge ring 112A of the reference example has an inner edge ring 112c and an outer edge ring 112d. The inner edge ring 112c is transferred and the outer edge ring 112d is fixed. When the inner edge ring 112c for replacement is placed on the electrostatic chuck 1111 after the worn inner edge ring 112c is unloaded, there are cases in which a part of the inner edge ring 112c hits the central region 111a (substrate supporting surface) as shown in FIG. 3A. “A” in FIG. 3A shows an example in which the inner side of the inner edge ring 112c is caught in the central region 111a and the inner edge ring 112c cannot be placed on the annular region 111b (ring supporting surface). For example, if the difference between the inner diameter of the inner edge ring 112c and the diameter of the central region 111a is smaller than the transfer accuracy (transfer error) of the edge ring and the position of the central region 111a is higher than the position of the annular region 111b, the inner edge ring 112c may not be properly placed.

Further, the inner edge ring 112c and the outer edge ring 112d are annular members divided in a radial direction, and the dividing plane is vertical. In this case, a gap perpendicular to the surface of the electrostatic chuck 1111 is formed between the inner edge ring 112c and the outer edge ring 112d. When ions enter through the gap, the electrostatic chuck 1111 exposed through the gap is damaged or the portion of the outer edge ring 112d near the gap is worn as shown in “B” in FIG. 3B.

Therefore, an edge ring structure is provided that can align the inner edge ring 112a and the outer edge ring 112b so that the inner edge ring 112a is properly placed regardless of the transfer accuracy when the inner edge ring 112a is replaced by the elevating part 50. Further, an edge ring structure is provided that can prevent damage to the electrostatic chuck 1111 and wear of the outer edge ring 112d.

(Edge Ring)

First, the structure of the edge ring according to the embodiment is described with reference to FIG. 2. The ring assembly 112 includes the edge ring divided into the inner edge ring 112a and the outer edge ring 112b. The ring assembly 112 further includes the cover ring 113a and the insulating member 113b. The ring members include the inner edge ring 112a, the outer edge ring 112b, the cover ring 113a, and the insulating member 113b.

The inner edge ring 112a is an annular member and is provided around the substrate W. The inner edge ring 112a may be made of a conductive material including, for example, Si and SiC. The inner edge ring 112a is disposed on the outer edge ring 112b. The outer edge ring 112b has an outer peripheral portion higher than the substrate W placed on the central region 111a and an inner peripheral portion lower than the outer peripheral portion, and the inner edge ring 112a is disposed on an upper surface 12b2 of the inner peripheral portion.

The outer edge ring 112b is an annular member and is provided around the inner edge ring 112a. The outer edge ring 112b may be made of a conductive material including, for example, Si, SiC, or the like. The outer edge ring 112b is disposed in the annular region 111b. The inner edge ring 112a and the outer edge ring 112b may be made of the same material. The inner edge ring 112a and the outer edge ring 112b may be made of different materials.

In the example of FIG. 2, the cover ring 113a is disposed to cover the outer edge ring 112b. Further, the insulating member 113b is disposed to cover the outer peripheries of the electrostatic chuck 1111 and the base 1110 and to support the cover ring 113a thereon. The cover ring 113a and the insulating member 113b are annular members made of a dielectric material. One example includes quartz (SiO₂).

The outer edge ring 112b has a first alignment portion and the inner edge ring 112a has a second alignment portion. The outer edge ring 112b has a substantially vertical outer peripheral surface and faces a side wall of the cover ring 113a. At least a portion of the inner peripheral surface of the outer edge ring 112b is formed with a tapered surface that becomes lower toward the inner side. A portion of the inner peripheral surface of the outer edge ring 112b of the present disclosure is a tapered surface 12b1, and a portion of the inner peripheral surface is a horizontal surface (upper surface 12b2). However, the present disclosure is not limited thereto, and the entire inner peripheral surface of the outer edge ring 112b may be tapered. The tapered surface 12b1 is an example of the first alignment portion.

The inner edge ring 112a has a vertical inner peripheral surface (inner peripheral edge) and faces a side wall of the electrostatic chuck 1111. At least a portion of the outer peripheral surface of the inner edge ring 112a is formed with a tapered surface that becomes lower toward the inner side. The inner edge ring 112a of the present disclosure has a tapered surface 12a1 on the entire outer peripheral surface. However, the present disclosure is not limited thereto, and a portion of the outer peripheral surface of the inner edge ring 112a may be tapered. The tapered surface 12a1 is an example of the second alignment portion.

For ease of description, the region corresponding to the tapered surface 12b1 of the outer edge ring 112b is defined as an intermediate portion, the outer peripheral side of the intermediate portion is defined as an outer peripheral portion (the region corresponding to an upper surface 12b3), and the inner peripheral side of the intermediate portion is defined as an inner peripheral portion (the region corresponding to the upper surface 12b2). The upper surface 12b2 of the inner peripheral portion serves as a placing surface for the inner edge ring 112a. The inner edge ring 112a and the outer edge ring 112b are configured such that the tapered surface 12a1 and the tapered surface 12b1 align the inner edge ring 112a and the outer edge ring 112b. As a result, the inner edge ring 112a is positioned at a correct position where a lower surface 12a2 of the inner edge ring 112a faces the upper surface 12b2 of the outer edge ring 112b regardless of the transfer accuracy.

The outer peripheral portion of the outer edge ring 112b is formed thicker in the height direction (vertical direction) than the intermediate portion and the inner peripheral portion. Therefore, the height of the upper surface 12b3 of the outer peripheral portion is higher than the height of the upper surface 12b2 of the inner peripheral portion. The tapered surface 12b1 is a surface connecting the upper surface 12b3 of the outer peripheral portion and the upper surface 12b2 of the inner peripheral portion, thereby defining the angle θ of the tapered surface 12b1.

When the inner edge ring 112a is placed on the outer edge ring 112b, the upper surface 12a3 of the inner edge ring 112a is at the same height as an upper surface of the substrate W and lower than the upper surface 12b3 of the outer peripheral portion of the outer edge ring 112b. The angle of the tapered surface 12a1 of the inner edge ring 112a is (180°−θ) with respect to the angle θ of the tapered surface 12b1 of the outer edge ring 112b. The angle θ of the tapered surface 12b1 is 45° or more. Therefore, the angle of the tapered surface 12a1 is 135° or less. The angle θ of the tapered surface 12b1 is, for example, less than 90°, may be any angle that allows positioning (alignment) of the inner edge ring 112a and the outer edge ring 112b by aligning the tapered surfaces 12a1 and 12b1, and is preferably, for example, 45°.

The tapered surface 12a1 of the inner edge ring 112a and the tapered surface 12b1 of the outer edge ring 112b have a tapered shape all around in the circumferential direction. However, the present disclosure is not limited thereto, and the tapered surface 12a1 and the tapered surface 12b1 may be partially tapered in the circumferential direction. However, at a position where the inner edge ring 112a is the tapered surface 12a1, the outer edge ring 112b is also the tapered surface 12b1 so as to be aligned.

The inner diameter of the inner edge ring 112a and the inner diameter of the outer edge ring 112b are the same, and the outer diameter of the inner edge ring 112a is smaller than the outer diameter of the outer edge ring 112b. The inner edge ring 112a and the outer edge ring 112b at least partially overlap when viewed from above. In the example of FIG. 2, the outer edge ring 112b overlaps the entire inner edge ring 112a when viewed from above, but the present disclosure is not limited thereto, and the outer edge ring 112b may overlap a portion of the inner edge ring 112a when viewed from above. That is, it is sufficient that the outer edge ring 112b is provided around the inner edge ring 112a, and at least the outer peripheral portion of the inner edge ring 112a and the inner peripheral portion of the outer edge ring 112b overlap when viewed from above.

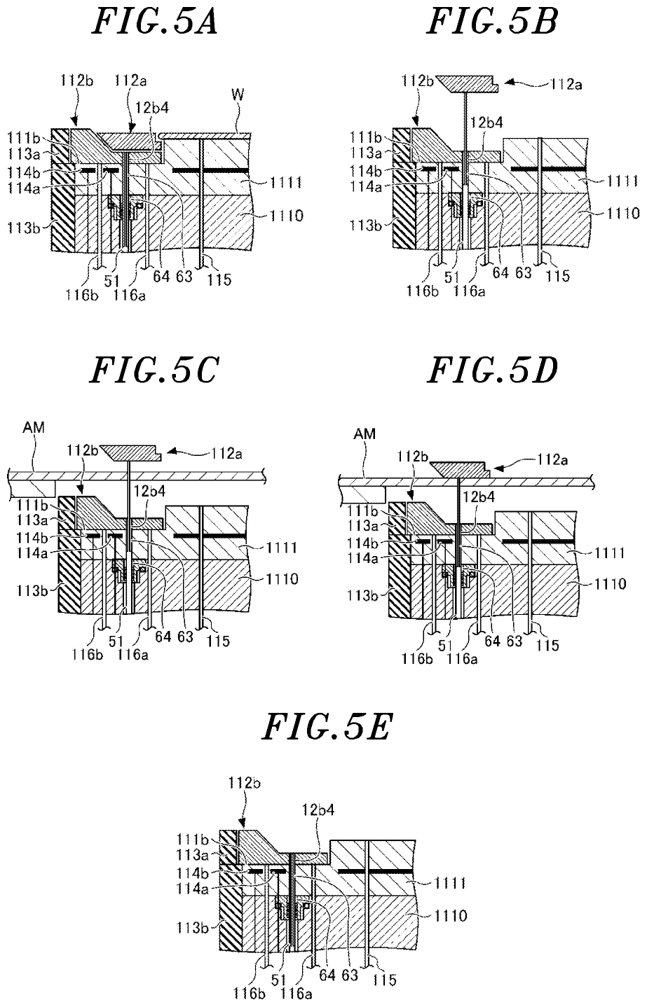

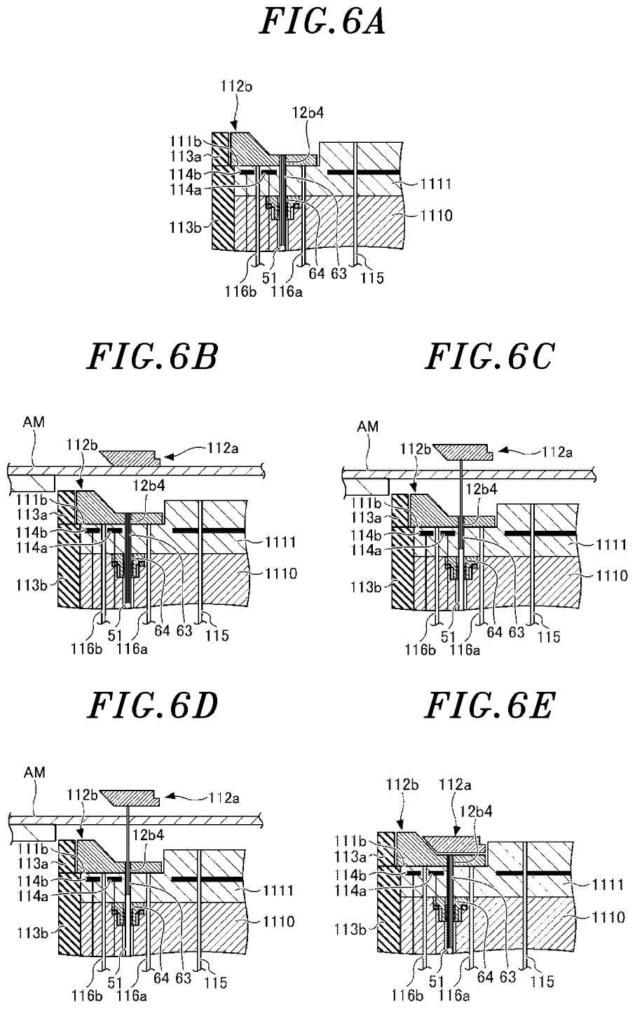

When the elevating part 50 replaces the inner edge ring 112a, the worn inner edge ring 112a is unloaded and the inner edge ring 112a for replacement is placed on the outer edge ring 112b. At this time, the tapered structure of the inner edge ring 112a and the outer edge ring 112b enables alignment in the horizontal direction. Therefore, it is possible to eliminate a misalignment of the inner edge ring 112a due to the transfer and to place the inner edge ring 112a for replacement at the correct position. As a result, the tapered surface 12a1 of the inner edge ring 112a is guided by the tapered surface 12b1 of the outer edge ring 112b regardless of the transfer accuracy of a transfer arm AM (see FIGS. 5A to 5E and 6A to 6E, which will be described later). Thereby, the center axis of the inner edge ring 112a and the center axis of the outer edge ring 112b can be aligned.

Further, the incident angle of the ions is approximately perpendicular to the substrate W. Similarly, the ions also enter the ring assembly 112 disposed on the outer peripheral side of the substrate W substantially perpendicularly. In the reference example shown in FIGS. 3A and 3B, the outer peripheral surface of the inner edge ring 112c and the inner peripheral surface of the outer edge ring 112d are vertical, and a vertical gap is formed between the outer peripheral surface of the inner edge ring 112c and the inner peripheral surface of the outer edge ring 112d. Therefore, the ions may pass through this vertical gap and damage the electrostatic chuck 1111. On the other hand, in the configuration shown in FIG. 2, a gap formed between the tapered surface 12a1 of the inner edge ring 112a and the tapered surface 12b1 of the outer edge ring 112b has the angle θ. Therefore, the tapered surface 12a1 and the tapered surface 12b1 face each other, and this structure makes it difficult for the ions to enter the gap. Further, the electrostatic chuck 1111 is not exposed from the gap between the inner edge ring 112a and the outer edge ring 112b. This can prevent ions from entering through the gap between the tapered surface 12a1 and the tapered surface 12b1, damaging the electrostatic chuck 1111 and wearing the outer edge ring 112b. This makes it possible to prolong the service life of the outer edge ring 112b and the electrostatic chuck 1111, while automatically replacing the inner edge ring 112a for replacement without exposing it to the atmosphere.

(Elevating Part)

Next, the configuration of the elevating part 50 is described with reference to FIG. 2. The plasma processing apparatus according to the embodiment includes the elevating part 50 for transferring the edge ring placed on the electrostatic chuck 1111. In the present embodiment, an example will be described in which the elevating part 50 transfers the inner edge ring 112a.

The elevating part 50 includes a lifter 54. The lifter 54 is configured to raise and lower at least one of the inner edge ring 112a and the outer edge ring 112b. In the present disclosure, the lifter 54 is configured to raise and lower the inner edge ring 112a. The lifter 54 has a pin 51 and an actuator 53 that raises and lowers the pin 51.

When the inner edge ring 112a and the outer edge ring 112b are placed, the inner edge ring 112a covers the inner peripheral portion and the intermediate portion of the outer edge ring 112b from above. Therefore, the inner peripheral portion and the intermediate portion of the outer edge ring 112b are not exposed to the plasma processing space. A through hole 12b4 is formed in the inner peripheral portion of the outer edge ring 112b so as to penetrate the outer edge ring 112b in the vertical direction (thickness direction).

The annular region 111b of the electrostatic chuck 1111 is formed with a through hole 63 penetrating the electrostatic chuck 1111 in the vertical direction at a position communicating with the through hole 12b4. Further, the base 1110 is formed with a through hole 64 penetrating the base 1110 in the vertical direction at a position communicating with the through hole 63.

The pin 51 is accommodated in the through hole 63 and the through hole 64 and is connected to the actuator 53 below. Hereinafter, the lower end of the pin 51 connected to the actuator 53 is referred to as a base end, and the upper end thereof is referred to as a tip end. A sealing portion 52 is disposed in the through hole 64 and allows the pin 51 to be raised and lowered while sealing the vacuum space on the tip end side from the atmospheric space on the base end side. The pin 51 extends downwardly through the sealing portion 52. The sealing portion 52 is, for example, a shaft seal, bellows, or the like. The actuator 53 drives the pin 51 so that it can be raised and lowered. The type of the actuator 53 is not particularly limited. The actuator 53 is, for example, a piezo actuator, a motor, or the like.

The pin 51 has a first holding portion 51a, a second holding portion 51b, and a protruding portion 51c. The first holding portion 51a has a predetermined length from the tip end of the pin 51 to the protruding portion 51c. The first holding portion 51a has a cross section that fits into the through hole 12b4 with a predetermined clearance. The second holding portion 51b is axially connected to the base end side of the first holding portion 51a. The protruding portion 51c protruding outwardly from the first holding portion 51a is formed at a position where the second holding portion 51b and the first holding portion 51a are connected. A cross section of the second holding portion 51b at a position where the protruding portion 51c is formed has a size or shape that does not fit into the through hole 12b4. That is, when the pin 51 is inserted into the through hole 12b4 from the lower surface side of the outer edge ring 112b, the first holding portion 51a passes through the through hole 12b4 and rises so as to protrude from the upper surface 12b2 of the outer edge ring 112b. Then, the pin 51 can be raised until the protruding portion 51c contacts the lower surface of the outer edge ring 112b. The second holding portion 51b is configured to stop at an entrance of the through hole 12b4 and support the outer edge ring 112b from the lower surface by the protruding portion 51c. As a result, only the inner edge ring 112a can be raised by the pin 51 and replaced. When the outer edge ring 112b is not fixed and the outer edge ring 112b is transferred together with the inner edge ring 112a, the second holding portion 51b supports the outer edge ring 112b from the lower surface by the protruding portion 51c. In this state, the inner edge ring 112a and the outer edge ring 112b are raised by the pin 51 and replaced.

The specific shapes of the first holding portion 51a, the second holding portion 51b, and the protruding portion 51c are not particularly limited. For example, the first holding portion 51a and the second holding portion 51b may be coaxial rod-shaped members. When the first holding portion 51a and the second holding portion 51b are cylindrical, the diameter of the first holding portion 51a is smaller than the diameter of the second holding portion 51b. The protruding portion 51c protrudes in the circumferential direction by the same length as the diameter of the second holding portion 51b. The inner diameter of the through hole 12b4 is larger than the diameter of the first holding portion 51a and smaller than the diameter of the second holding portion 51b.

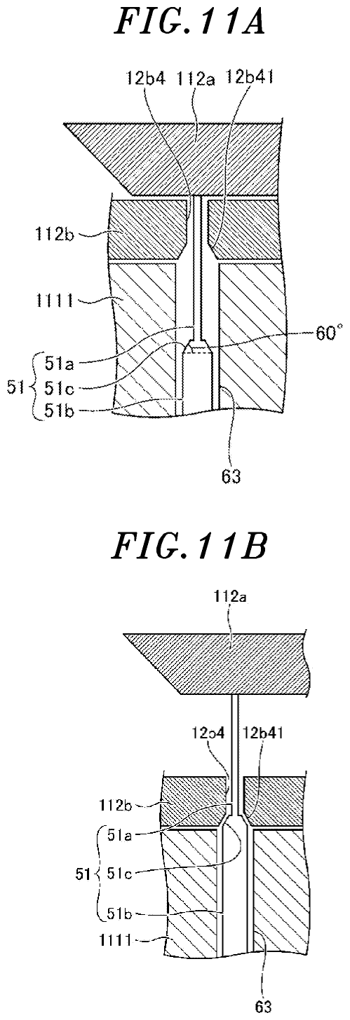

The first holding portion 51a and the second holding portion 51b may have polygonal cross-sections. Further, the cross-sectional area of the first holding portion 51a needs not be smaller than the cross-sectional area of the second holding portion 51b. It is sufficient that at least the protruding portion 51c protruding outwardly is formed on the tip end side of the second holding portion 51b. Such a structure will be described later (see FIGS. 11A and 11B or the like).

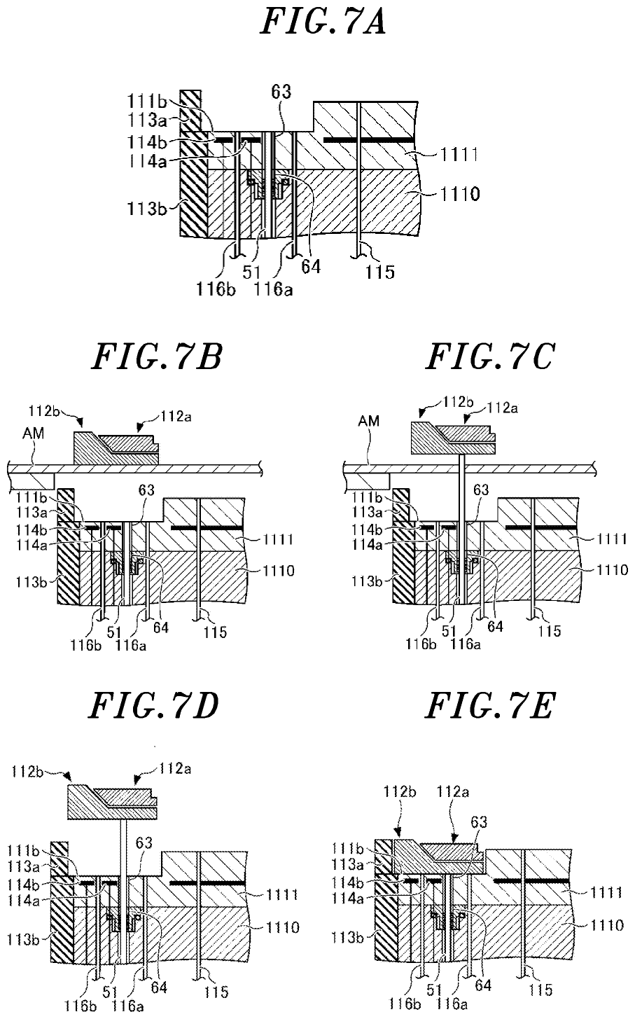

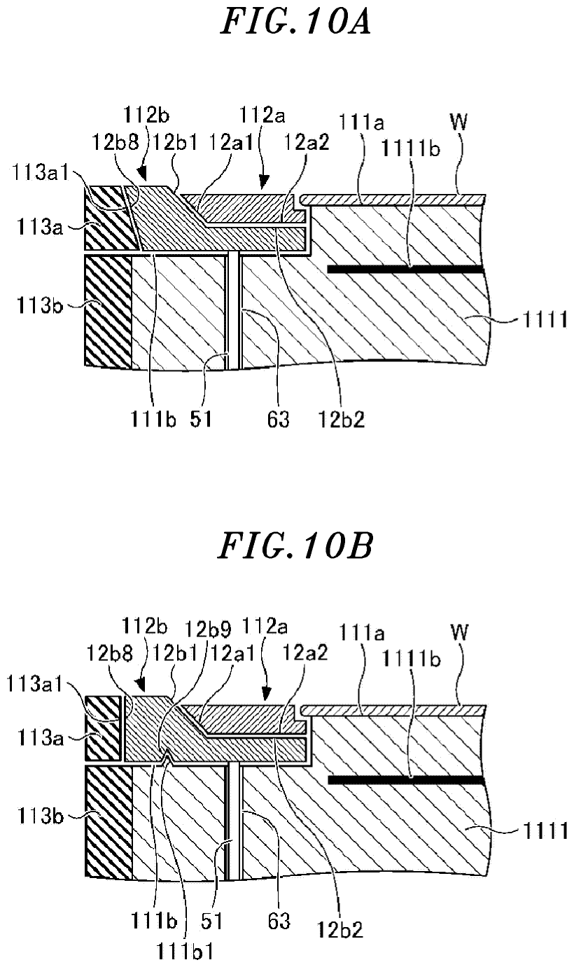

Three or more pins 51 are provided in the circumferential direction. There may be a structure in which the through hole 12b4 is not provided in the outer edge ring 112b and the pin 51 does not penetrate through the outer edge ring 112b. Such a structure will be described later (see FIGS. 7A to 7E, 10A, 10B and the like).

(Bipolar Electrostatic Chuck)

The electrostatic chuck 1111 includes an outer edge ring electrostatic chuck 1111c disposed at a position facing the outer edge ring 112b. The electrostatic chuck 1111 may include an inner edge ring electrostatic chuck 1111d (see FIGS. 9A to 9D) disposed at a position facing the inner edge ring 112a. The outer edge ring electrostatic chuck 1111c is a bipolar electrostatic chuck and includes an inner peripheral electrode 114a and an outer peripheral electrode 114b as the first electrostatic electrode 114. The inner peripheral electrode 114a and the outer peripheral electrode 114b are disposed in the ceramic member 1111a (see FIG. 1) of the outer edge ring electrostatic chuck 1111c. The inner peripheral electrode 114a and the outer peripheral electrode 114b may be metal plates or metal meshes.

The outer edge ring electrostatic chuck 1111c can attract and hold the outer edge ring 112b made of Si or SiC due to the potential difference between the inner peripheral electrode 114a and the outer peripheral electrode 114b. The inner peripheral electrode 114a and the outer peripheral electrode 114b are provided at a position of the outer edge ring electrostatic chuck 1111c that overlaps the outer edge ring 112b when viewed from above. In the present disclosure, the inner peripheral electrode 114a and the outer peripheral electrode 114b are provided at positions corresponding to the outer peripheral portion and the intermediate portion of the outer edge ring 112b, but the present disclosure is not limited thereto, and the inner peripheral electrode 114a and the outer peripheral electrode 114b may be provided at a position corresponding to the inner peripheral portion. The outer edge ring electrostatic chuck 1111c of the present disclosure is not limited to a bipolar electrostatic chuck, and may be a unipolar electrostatic chuck. In the case of a unipolar electrostatic chuck, it is possible to attract and hold the outer edge ring 112b due to the potential difference between the plasma and the first electrostatic electrode 114.

The inner peripheral electrode 114a is annularly disposed at the intermediate portion of the outer edge ring 112b on the inner peripheral side compared to the outer peripheral electrode 114b, and the outer peripheral electrode 114b is annularly disposed at the outer peripheral portion of the outer edge ring 112b. The inner peripheral electrode 114a is electrically connected to a DC power supply 33a through a switch 29a. A positive voltage or a negative voltage for attracting the outer edge ring 112b to the electrostatic chuck 1111 is selectively applied to the inner peripheral electrode 114a from the DC power supply 33a through the switch 29a. The polarity of the voltage applied to the inner peripheral electrode 114a from the DC power supply 33a is switched by the control device 2 (see FIG. 1). The DC power supply 33a is an example of the third DC generator 33.

The outer peripheral electrode 114b is electrically connected to a DC power supply 33b through a switch 29b. A positive voltage or a negative voltage for attracting the outer edge ring 112b to the electrostatic chuck 1111 is selectively applied to the outer peripheral electrode 114b from the DC power supply 33b through the switch 29b. The polarity of the voltage applied to the outer peripheral electrode 114b from the DC power supply 33b is switched by the control device 2. The DC power supply 33b is an example of the third DC generator 33. In addition to DC voltage, AC voltage may also be applied to the inner peripheral electrode 114a and the outer peripheral electrode 114b.

[Transfer Method]

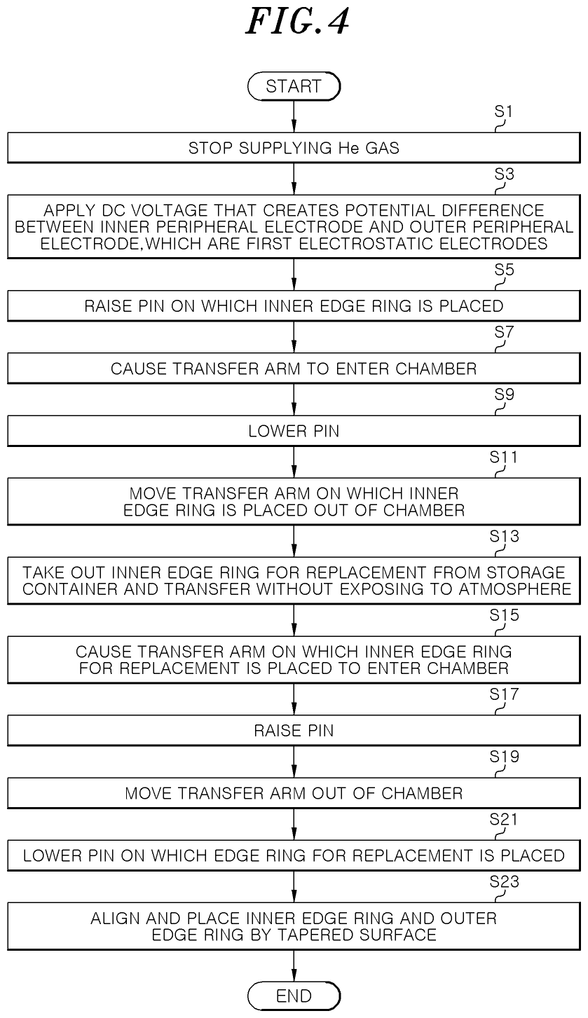

Next, the transfer (unloading) of the worn inner edge ring 112a by the elevating part 50 will be described with reference to FIGS. 2, 4, and 5A to 5E. Further, the transfer (loading) of the inner edge ring 112a for replacement by the elevating part 50 will be described with reference to FIGS. 2, 4, and 6A to 6E. FIG. 4 is a flow chart showing an example of a transfer method according to the embodiment. FIGS. 5A to 5E are diagrams explaining the transfer method according to the embodiment. FIGS. 6A to 6E are diagrams explaining the transfer method (continued from FIGS. 5A to 5E) according to the embodiment. FIG. 5E and FIG. 6A are the same diagram.

FIG. 5A is a simplified view of the same condition as in FIG. 2. As shown in FIG. 5A, the pin 51 is accommodated in the through hole 63 and the through hole 64 except when the edge ring is transferred. Although the tip end of the pin 51 is inserted into the through hole 12b4 of the outer edge ring 112b in the example of FIG. 5A, the tip end of the pin 51 may be accommodated below the outer edge ring 112b.

The inner edge ring 112a is transferred after the substrate W is unloaded. The transfer method of the present disclosure is controlled by the control device 2. The transfer method according to the present embodiment is not limited to the method for aligning the edge ring, and includes a method for aligning a ring member such as a cover ring.

When the transfer method of the present disclosure is started, the control device 2 controls the heat transfer gas supply to stop supplying He gas from the gas supply path 116 to between the rear surface of the outer edge ring 112b and the electrostatic chuck 1111 (annular region 111b) (step S1).

Next, the control device 2 controls the switch 29a or the switch 29b to select and apply a DC voltage that creates a potential difference between the inner peripheral electrode 114a and the outer peripheral electrode 114b, which are the first electrostatic electrodes (step S3). For example, when a DC voltage of 2500 V is applied to the inner peripheral electrode 114a and a DC voltage of 2500 V is applied to the outer peripheral electrode 114b during processing of the substrate W, the DC voltage applied from the DC power supply 33a to the inner peripheral electrode 114a is left unchanged. On the other hand, the switch 29b is switched to switch the polarity of the DC voltage applied from the DC power supply 33b to the outer peripheral electrode 114b so that a DC voltage of, for example, −2500 V is applied. As a result, the outer edge ring 112b is attracted to the electrostatic chuck 1111 by generating a potential difference between the inner peripheral electrode 114a and the outer peripheral electrode 114b.

In a state where the outer edge ring 112b is fixed to the electrostatic chuck 1111 in this manner, the control device 2 controls the actuator 53 to drive the pin 51. When the pin 51 rises, the first holding portion 51a penetrates through the through hole 12b4 of the outer edge ring 112b and contacts the lower surface of the inner edge ring 112a to lift the inner edge ring (step S5). FIG. 5B shows an example of a state in which the inner edge ring 112a is lifted by the elevating part 50 according to the embodiment.

Returning to FIG. 4, the control device 2 next causes a robot arm for transfer (hereinafter referred to as “transfer arm AM”) to enter the plasma processing chamber 10 (step S7). FIG. 5C is a diagram showing an example of a state immediately before the inner edge ring 112a, which has been lifted by the elevating part 50, is placed on the transfer arm AM. At this time, after the pin 51 has lifted the inner edge ring 112a, the control device 2 causes the transfer arm AM to enter above the substrate support 11 from outside the plasma processing chamber 10. The transfer arm AM advances horizontally at a height lower than the tip end of the pin 51.

Returning to FIG. 4, when the transfer arm AM is disposed below the inner edge ring 112a lifted by the pin 51, the control device 2 controls the actuator 53 to lower the pin 51 (step S9). FIG. 5D shows an example of a state in which the inner edge ring 112a lifted by the elevating part 50 is placed on the transfer arm AM. By lowering the pin 51, the inner edge ring 112a held on the pin 51 is placed on the transfer arm AM. After the inner edge ring 112a is placed on the transfer arm AM, the pin 51 continues to be lowered.

Returning to FIG. 4, next, when the pin 51 is accommodated in the through hole 63 and the through hole 64, the control device 2 moves the transfer arm AM on which the inner edge ring 112a is placed out of the plasma processing chamber 10 (step S11). FIG. 5E shows an example of a state when the elevating part 50 completes the transfer of the inner edge ring 112a. The transfer arm AM unloads the inner edge ring 112a from the plasma processing chamber 10, the pin 51 retracts to the position before the start of the transfer, and the transfer of the inner edge ring 112a is completed.

Returning to FIG. 4, next, the control device 2 takes out the inner edge ring 112a for replacement from a storage container using the transfer arm and transfers the inner edge ring 112a for replacement to the plasma processing chamber 10 without exposing it to the atmosphere (step S13). The storage container will be described later. The inner edge ring 112a for replacement may be transferred by the transfer arm AM or may be transferred by a plurality of transfer arms including the transfer arm AM.

Next, the control device 2 causes the transfer arm AM on which the inner edge ring 112a for replacement is placed to enter the plasma processing chamber 10 (step S15). FIG. 6B shows an example of a state in which the transfer arm AM on which the inner edge ring 112a for replacement is placed is advanced into the plasma processing chamber 10.

Returning to FIG. 4, next, the control device 2 controls the actuator 53 to raise the pin 51 (step S17). FIG. 6C shows an example of a state in which the inner edge ring 112a for replacement placed on the transfer arm AM is lifted by the pin 51. When the pin 51 rises, the inner edge ring 112a for replacement placed on the transfer arm AM is lifted and held by the pin 51.

Returning to FIG. 4, after the inner edge ring 112a is held on the pin 51, the transfer arm AM moves out of the plasma processing chamber 10 (step S19). FIG. 6D shows an example of a state in which the inner edge ring 112a for replacement is lifted by the pin 51 and the transfer arm AM is retracted.

Returning to FIG. 4, next, the control device 2 controls the actuator 53 to lower the pin 51 on which the inner edge ring 112a for replacement is placed (step S21). At this time, the pin 51 on which the inner edge ring 112a is placed is lowered while the outer edge ring 112b is electrostatically attracted to the outer edge ring electrostatic chuck 1111c. FIGS. 6D and 6E show an example of a state in which the inner edge ring 112a for replacement, which has been lifted by the pin 51, is placed on the electrostatically attracted outer edge ring 112b. By lowering the pin 51, the inner edge ring 112a held on the pin 51 is aligned with the outer edge ring 112b and placed (step S23). After the inner edge ring 112a is placed, the pin 51 continues to be lowered. This completes the processing. The control device 2 controls the heat transfer gas supply to start supplying He gas from the gas supply path 116 to between the rear surface of the outer edge ring 112b and the electrostatic chuck 1111 (annular region 111b), and processes the substrate W.

When replacing the inner edge ring 112a for replacement, the inner edge ring 112a and the outer edge ring 112b are aligned by the tapered surface 12a1 of the inner edge ring 112a and the tapered surface 12b1 of the outer edge ring 112b. As a result, the inner edge ring 112a for replacement is accurately positioned and placed so that the lower surface 12a2 of the inner edge ring 112a for replacement faces the upper surface 12b2 of the outer edge ring 112b regardless of the transfer accuracy of the elevating part 50. Further, when the inner edge ring 112a for replacement is replaced, the outer edge ring 112b is fixed to the outer edge ring electrostatic chuck 1111c. Thereby, the alignment accuracy can be improved. The inner edge ring 112a may be lowered while the outer edge ring 112b is not electrostatically attracted. However, if the inner edge ring 112a is lowered while the outer edge ring 112b is electrostatically attracted, since the outer side of the inner edge ring 112a is fixed, the placement accuracy of the inner side of the inner edge ring 112a can be further improved. For example, the processing of step S3 is not necessarily performed between steps S1 and S5 of FIG. 4. The processing of step S3 may be performed after the pin 51 is lowered in step S21 and before the inner edge ring 112a is placed on the outer edge ring 112b in step S23. That is, the processing of step S3 may be performed before the processing of step S23.

In this way, when the inner edge ring 112a is automatically replaced using the elevating part 50, the inner edge ring 112a for replacement can be placed in the correct position by aligning the tapered surface 12b1 with the tapered surface 12a1. As a result, transfer errors can be suppressed.

Further, the tapered surface 12a1 and the tapered surface 12b1 make it difficult for ions to enter the gap between the inner edge ring 112a and the outer edge ring 112b. Further, the electrostatic chuck 1111 is not exposed from the gap between the inner edge ring 112a and the outer edge ring 112b. As a result, it is possible to prevent the electrostatic chuck 1111 from being damaged and the outer edge ring 112b from being worn by ions entering through the gap. This makes it possible to prolong the service life of the outer edge ring 112b and the electrostatic chuck 1111 while automatically replacing the inner edge ring 112a for replacement without exposing it to the atmosphere.

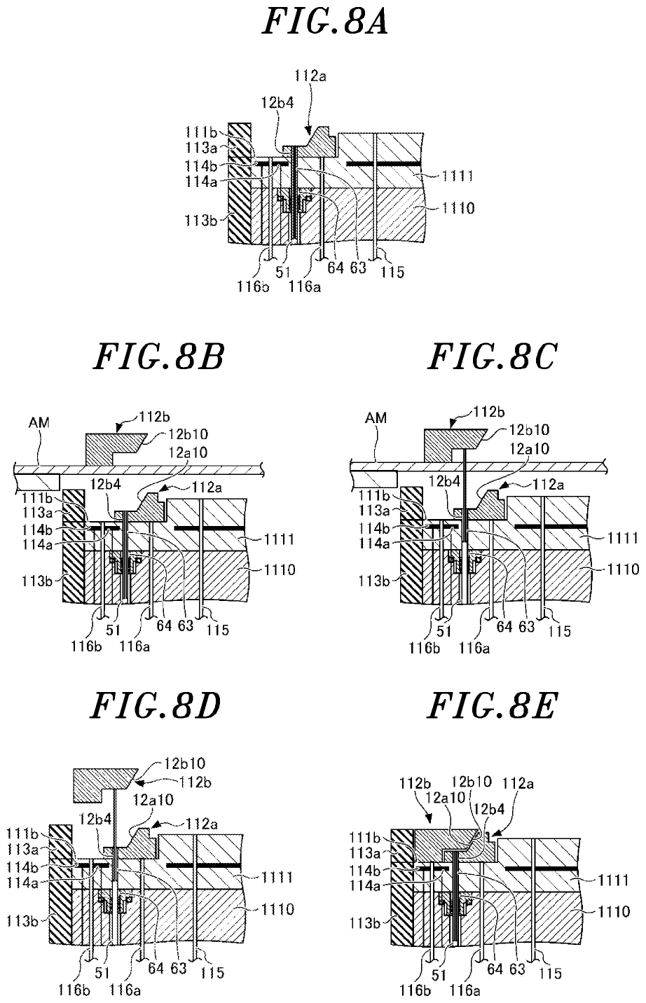

As described above, an example has been given in which the inner edge ring 112a is automatically replaced using the elevating part 50, but the present disclosure is not limited thereto. For example, as shown in FIGS. 7A to 7E and 8A to 8E, the outer edge ring 112b may be lifted by the lifter 54 and automatically transferred. In FIGS. 7A to 7E, the outer edge ring 112b is lifted and automatically transferred at the same time as the inner edge ring 112a. The objects to be transferred in FIGS. 7A to 7E are the outer edge ring 112b and the inner edge ring 112a, which are different from the inner edge ring 112a, which is the object to be transferred in FIGS. 6A to 6E. Further, in this example, the pin 51 may have the same thickness from the base end to the tip end because it does not penetrate through the outer edge ring 112b or the inner edge ring 112a. However, even in this case, the pin 51 may have a shape in which the tip end is thinner than the base end. Since the loading operation in FIGS. 7A to 7E corresponds to the loading operation in FIGS. 6A to 6E, description thereof is omitted. In this case, the inner edge ring 112a and the outer edge ring 112b are also positioned by the tapered surfaces 12a1 and 12b1 (see FIG. 2). Since the unloading operation of the outer edge ring 112b and the inner edge ring 112a performed before the loading operation in FIGS. 7A to 7E is the operation performed from FIG. 7E to FIG. 7A, description thereof is omitted.

Similarly, in FIGS. 8A to 8E, only the outer edge ring 112b is lifted and automatically transferred. The object to be transferred in FIGS. 8A to 8E is the outer edge ring 112b, which is different from the inner edge ring 112a, which is the object to be transferred in FIGS. 6A to 6E. Since the loading operation in FIGS. 8A to 8E corresponds to the loading operation in FIGS. 6A to 6E, description thereof is omitted. In this case as well, the inner edge ring 112a and the outer edge ring 112b are positioned by tapered surfaces 12a10 and 12b10 shown in FIGS. 8A to 8E. Since the unloading operation of the outer edge ring 112b performed before the loading operation in FIGS. 8A to 8E is the operation performed from FIG. 8E to FIG. 8A, description thereof is omitted. Although not shown, the inner edge ring 112a in FIGS. 8A to 8E may be fixed by a bipolar electrostatic chuck.

### Modified Examples

Modified examples 1 to 4 of the edge ring and its peripheral structure described above are described with reference to FIGS. 9A to 9D. FIGS. 9A to 9D are diagrams showing the modified examples 1 to 4 of the edge ring and its peripheral structure according to the embodiment. The edge rings of the modified examples 1 to 4 shown in FIGS. 9A to 9D are also divided into the inner edge ring 112a and the outer edge ring 112b. Further, the inner edge ring 112a and the outer edge ring 112b at least partially overlap when viewed from above. Although not shown, the inner edge ring 112a in FIG. 9B may be fixed by a bipolar electrostatic chuck.

FIG. 9A shows the modified example 1 of the edge ring of the present disclosure. The modified example 1 shows a structure in which each of the inner edge ring 112a and the outer edge ring 112b includes two tapered surfaces. The tapered surface 12a1 of the inner edge ring 112a faces the tapered surface 12b1 of the outer edge ring 112b, and a tapered surface 12a5 of the inner edge ring 112a faces a tapered surface 12b5 of the outer edge ring 112b. The tapered surface 12b1 and the tapered surface 12b5 of the outer edge ring 112b are examples of the first alignment portion. The tapered surface 12a1 and the tapered surface 12a5 of the inner edge ring 112a are examples of the second alignment portion. The inner edge ring 112a and the outer edge ring 112b are aligned by the tapered surface 12a1 and the tapered surface 12a5 of the inner edge ring 112a and the tapered surface 12b1 and the tapered surface 12b5 of the outer edge ring 112b.

In the modified example 1, the outer edge ring 112b and a part of the inner edge ring 112a are placed on the annular region 111b. Further, in the modified example 1, the backside gas is supplied from the heat transfer gas supply having the gas supply path 116a and the gas supply path 116b. The groove 201b of 50 μm to hundreds of μm is formed annularly in the rear surface of the outer edge ring 112b corresponding to the gas supply path 116b.

The electrostatic chuck 1111 includes the outer edge ring electrostatic chuck 1111c disposed at the position facing the outer edge ring 112b, and the inner edge ring electrostatic chuck 1111d disposed at the position facing the inner edge ring 112a. The outer edge ring electrostatic chuck 1111c is a bipolar electrostatic chuck and includes the inner peripheral electrode 114a and the outer peripheral electrode 114b as the first electrostatic electrode 114. The inner peripheral electrode 114a and the outer peripheral electrode 114b are disposed in the ceramic member 1111a (see FIG. 1) of the outer edge ring electrostatic chuck 1111c. The inner edge ring electrostatic chuck 1111d is a unipolar electrostatic chuck and includes the second electrostatic electrode 118. The second electrostatic electrode 118, the inner peripheral electrode 114a, and the outer peripheral electrode 114b may be metal plates or metal meshes.

The inner peripheral electrode 114a is electrically connected to the DC power supply 33a through the switch 29a. The outer peripheral electrode 114b is electrically connected to the DC power supply 33b through the switch 29b. A DC voltage is applied to the inner peripheral electrode 114a and the outer peripheral electrode 114b from the DC power supplies 33a and 33b. The second electrostatic electrode 118 is electrically connected to a DC power supply 33c through a switch 29c. A DC voltage is applied to the second electrostatic electrode 118 from the DC power supply 33c.

The outer edge ring electrostatic chuck 1111c and the inner edge ring electrostatic chuck 1111d may be bipolar electrostatic chucks or unipolar electrostatic chucks. By applying a specific DC voltage from the DC power supply 33a to the inner peripheral electrode 114a and the outer peripheral electrode 114b through the switches 29a and 29b, the outer edge ring 112b can be attracted to the electrostatic chuck 1111c. Further, by applying a specific DC voltage from the DC power supply 33c to the second electrostatic electrode 118 through the switch 29c, the inner edge ring 112a can be attracted to the electrostatic chuck 1111d. The DC power supplies 33a, 33b, and 33c are examples of the third DC generator 33.

FIG. 9B shows the modified example 2 of the edge ring of the present disclosure. The modified example 2 shows a structure in which each of the inner edge ring 112a and the outer edge ring 112b includes one tapered surface. The tapered surface 12a1 of the inner edge ring 112a faces the tapered surface 12b1 of the outer edge ring 112b. The tapered surface 12b1 of the outer edge ring 112b is an example of the first alignment portion. The tapered surface 12a1 of the inner edge ring 112a is an example of the second alignment portion. The inner edge ring 112a and the outer edge ring 112b are aligned by the tapered surface 12a1 of the inner edge ring 112a and the tapered surface 12b1 of the outer edge ring 112b.

In the modified example 2, the outer edge ring 112b and the inner edge ring 112a are placed on the annular region 111b. The configurations and functions of the first electrostatic electrode 114 and the second electrostatic electrode 118 are the same as in the modified example 1. In the modified example 2, there is no through hole through which the pin 51 is inserted in the outer edge ring 112b. The pin 51 is configured to directly lift the lower surface of the inner edge ring 112a placed on the annular region 111b. Therefore, in the modified example 2, the pin 51 does not need to have a stepped structure as shown in FIG. 9A and has the same thickness from the base end to the tip end. However, the stepped pin 51 may also be used in the modified example 2. The stepped pin 51 may also be used for the pin 51 of FIGS. 9C and 9D.

FIG. 9C shows the modified example 3 of the edge ring of the present disclosure. The modified example 3 shows a structure in which each of the inner edge ring 112a and the outer edge ring 112b includes one tapered surface. The tapered surface 12a5 of the inner edge ring 112a faces the tapered surface 12b5 of the outer edge ring 112b. The tapered surface 12b5 of the outer edge ring 112b is an example of the first alignment portion. The tapered surface 12a5 of the inner edge ring 112a is an example of the second alignment portion. The inner edge ring 112a and the outer edge ring 112b are aligned by the tapered surface 12a5 of the inner edge ring 112a and the tapered surface 12b5 of the outer edge ring 112b.

In the modified example 3, the outer edge ring 112b and a part of the inner edge ring 112a are placed on the annular region 111b. The configurations and functions of the first electrostatic electrode 114 and the second electrostatic electrode 118 are the same as in the modified example 1.

In the modified example 3, there is no through hole through which the pin 51 is inserted in the outer edge ring 112b. The pin 51 is configured to directly lift the lower surface of the outer edge ring 112b placed on the annular region 111b. Thus, in the modified example 3, both the outer edge ring 112b and the inner edge ring 112a can be transferred.

FIG. 9D shows the modified example 4 of the edge ring of the present disclosure. In the modified example 4, the inner edge ring 112a and the outer edge ring 112b do not include a tapered surface. A horizontal surface 12a6 of the inner edge ring 112a faces a horizontal surface 12b6 of the outer edge ring 112b. An annular recess 12a7 is formed on the horizontal surface 12a6. However, the recess 12a7 is not limited to being provided all around in the circumferential direction and may be provided at least partially. A protrusion 12b7 is formed on the horizontal surface 12b6 at a position corresponding to the recess 12a7. When the recess 12a7 is provided all around in the circumferential direction, the protrusion 12b7 is also provided all around in the circumferential direction. When the recess 12a7 is partially provided in the circumferential direction, the protrusion 12b7 is also provided at a position corresponding to the recess 12a7 in the circumferential direction. The pin 51 is disposed at the same position as the protrusion 12b7 in the circumferential direction. Alternatively, the pin 51 may be disposed radially inside or outside the protrusion 12b7.

The protrusion 12b7 of the outer edge ring 112b is an example of the first alignment portion. The recess 12a7 of the inner edge ring 112a is an example of the second alignment portion. The inner edge ring 112a and the outer edge ring 112b are aligned by the recess 12a7 of the inner edge ring 112a and the protrusion 12b7 of the outer edge ring 112b. The inner edge ring 112a may have a protrusion and the outer edge ring 112b may have a recess at a position corresponding thereto.

The alignment portion may have a tapered surface as well as a protrusion and a recess. Further, the alignment portion may be formed only on the outer edge ring 112b. For example, recesses or protrusions (not shown) may be formed on the lower surface of the outer edge ring 112b. Further, protrusions or recesses may be formed at positions corresponding to the outer edge ring 112b of the electrostatic chuck 1111 (annular region 111b) so as to engage with recesses or protrusions formed on the outer edge ring 112b. This also allows the outer edge ring 112b to be automatically aligned with the electrostatic chuck 1111 by aligning the recesses and protrusions of the outer edge ring 112b and the electrostatic chuck 1111 when the outer edge ring 112b is replaced.

In the modified examples 1 to 4 shown in FIGS. 9A to 9D, the thickness of the thickest portion of the inner edge ring 112a is thicker than that of the inner edge ring 112a of FIG. 2. The inner peripheral side wall of the inner edge ring 112a and the inner peripheral portion of the outer edge ring 112b (the portion on which the inner edge ring 112a is placed in FIG. 2) are particularly likely to be worn by the plasma. Therefore, in the modified examples 1 to 4, the thickness of the inner edge ring 112a and/or the thickness of the inner peripheral portion of the outer edge ring 112b are increased. As a result, the replacement interval of the inner edge ring 112a can be extended and the service life of the outer edge ring 112b can be extended.

In the modified examples 1 to 4 shown in FIGS. 9A to 9D, the electrostatic chuck 1111 includes the outer edge ring electrostatic chuck 1111c disposed at the position facing the outer edge ring 112b of the substrate support 11. The outer edge ring electrostatic chuck 1111c is a bipolar electrostatic chuck and includes the inner peripheral electrode 114a and the outer peripheral electrode 114b as the first electrostatic electrode 114. The inner peripheral electrode 114a and the outer peripheral electrode 114b are disposed in the ceramic member 1111a of the electrostatic chuck 1111c. The inner peripheral electrode 114a and the outer peripheral electrode 114b may be metal plates or metal meshes. In addition, the electrostatic chuck 1111 includes the inner edge ring electrostatic chuck 1111d disposed at the position facing the inner edge ring 112a of the substrate support 11. The inner edge ring electrostatic chuck 1111d is a unipolar electrostatic chuck and includes the second electrostatic electrode 118. However, the inner edge ring electrostatic chuck 1111d may be a bipolar electrostatic chuck having an inner peripheral electrode and an outer peripheral electrode instead of the second electrostatic electrode 118. The second electrostatic electrode 118 is disposed in the ceramic member of the electrostatic chuck 1111d. The second electrostatic electrode 118 may be a metal plate or a metal mesh.

Modified examples 5 and 6 of the edge ring and its peripheral structure will be described with reference to FIGS. 10A and 10B. FIGS. 10A and 10B are diagrams showing modified examples 5 and 6 of the edge ring and its peripheral structure according to the embodiment. The edge rings of the modified examples 5 and 6 shown in FIGS. 10A and 10B are also divided into the inner edge ring 112a and the outer edge ring 112b. Further, the inner edge ring 112a and the outer edge ring 112b overlap each other at least partially when viewed from above.

FIG. 10A shows the modified example 5 of the edge ring of the present disclosure. In the modified example 5, both an inner peripheral surface 113a1 of the cover ring 113a (the surface facing the outer edge ring 112b) and an outer peripheral surface 12b8 of the outer edge ring 112b are tapered surfaces that become lower toward the inner side, and the positioning is performed by the tapered surfaces. In FIG. the outer edge ring 112b and the inner edge ring 112a are configured to be transferred by the pin 51. The cover ring 113a may be configured to be transferred by the pin 51.

FIG. 10B shows the modified example 6 of the edge ring of the present disclosure. In the modified example 6, both the inner peripheral surface 113a1 of the cover ring 113a and the outer peripheral surface 12b8 of the outer edge ring 112b are vertical surfaces and have no structure for positioning. In FIG. 10B, a protrusion 111b1 is formed on the annular region 111b of the electrostatic chuck 1111, and a recess 12b9 is formed on the rear surface of the outer edge ring 112b at a position corresponding to a position of the protrusion 111b1. The recess 12b9 is a concave portion corresponding to the shape of the protrusion 111b1, and the protrusion 111b1 is accommodated in the recess 12b9, thereby performing the positioning. As in FIG. 9D, the recess and the protrusion are not limited to being provided all around in the circumferential direction and may be provided at least partially. Further, the number of the protrusions 111b1 and the recesses 12b9 is not limited to one in the radial direction and may be plural. The number of the recesses and the protrusions in FIG. 9D is not limited to one in the radial direction and may be plural.

An example of a positioning structure using the pin 51 is described with reference to FIGS. 11A and 11B. FIGS. 11A and 11B are diagrams showing an example of a positioning structure using the pin 51 according to the embodiment. The pin 51 has the first holding portion 51a, the second holding portion 51b, and the protruding portion 51c. The first holding portion 51a has a predetermined length from the tip end of the pin 51 to the protruding portion 51c. The second holding portion 51b is axially connected to the base end side of the first holding portion 51a. The protruding portion 51c, which protrudes obliquely outward and downward from the first holding portion 51a, is formed at the position where the second holding portion 51b and the first holding portion 51a are connected to each other. For example, the protruding portion 51c may have an angle of 60° between a horizontal plane perpendicular to the axis of the pin 51 and a tapered surface of the protruding portion 51c. However, this angle is not limited to 60° and may be less than 90°.

As shown in FIG. 11A, the through hole 12b4 formed in the outer edge ring 112b and through which the pin 51 penetrates has a tapered surface 12b41 corresponding to the tapered surface of the protruding portion 51c. As a result, when the first holding portion 51a is inserted into the through hole 12b4, the protruding portion 51c is accommodated in the space within the through hole 12b4 formed by the tapered surface 12b41, and the positioning is performed.

[Transfer from Storage Container]

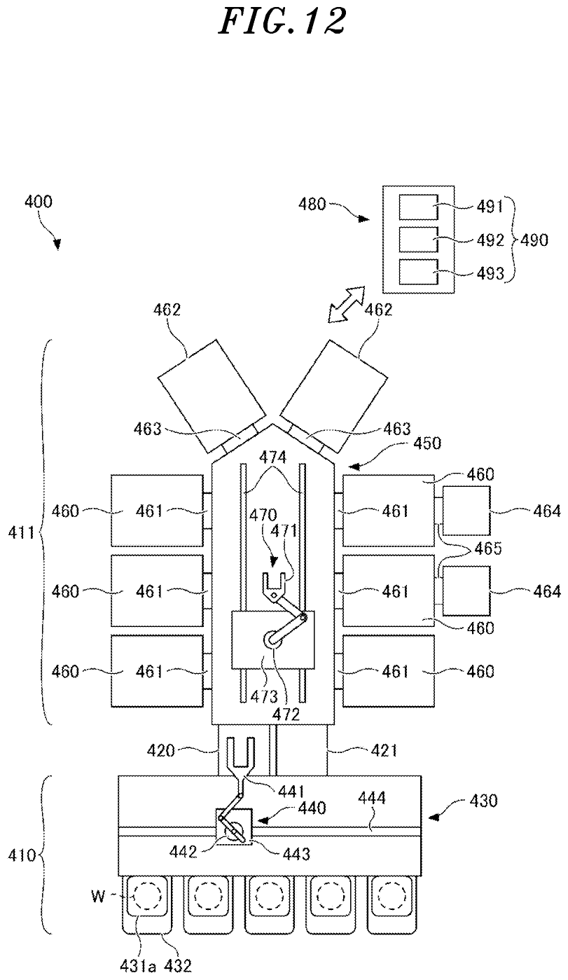

Next, an example of a method for transferring the edge ring from the storage container at the time of replacement of the edge ring is described with reference to FIG. 12. FIG. 12 is a diagram showing an example of a substrate processing system 400 according to the embodiment. In the substrate processing system 400, plasma processing such as etching, film formation, and diffusion is performed on the substrate W.

The substrate processing system 400 includes an atmosphere part 410 and a decompression part 411, and the atmosphere part 410 and the decompression part 411 are integrally connected via load lock modules 420 and 421. The atmospheric part 410 includes an atmospheric module that performs desired processing on the substrate W under an atmospheric pressure. The decompression part 411 includes a decompression module that performs desired processing on the substrate W in a decompressed atmosphere.

The load lock modules 420 and 421 are provided to connect a loader module 430 of the atmosphere part 410 and a transfer module 450 of the decompression part 411 via gate valves (not shown). The load lock modules 420 and 421 are configured to allow the interior to be switched between an atmospheric pressure atmosphere and a decompressed atmosphere (vacuum state).

The atmospheric part 410 includes the loader module 430 having a transfer device 440 and load ports 432 on which a plurality of FOUPs 431a are placed. A plurality of substrates W can be stored in the FOUP 431a. A FOUP 431b may be placed which can store a plurality of edge rings. The loader module 430 may be provided with an orienter module (not shown) that adjusts the horizontal orientation of the substrate W and the edge ring.

The loader module 430 has a rectangular housing therein, and the interior of the housing is maintained at an atmospheric pressure atmosphere. A plurality of, for example, five load ports 432 are arranged side by side on one long side surface of the housing of the loader module 430. The load lock modules 420 and 421 are arranged side by side on the other long side surface of the housing of the loader module 430.

Inside the loader module 430, the transfer device 440 for transferring the substrate W and the edge ring is provided. The transfer device 440 includes a transfer arm 441 that moves while supporting the substrate W and the edge ring, a rotary table 442 that rotatably supports the transfer arm 441, and a base 443 on which the rotary table 442 is mounted. Further, a guide rail 444 extending in the longitudinal direction of the loader module 430 is provided inside the loader module 430. The base 443 is provided on the guide rail 444, and the transfer device 440 is configured to be movable along the guide rail 444.

The decompression part 411 includes the transfer module 450, which transfers the substrate W and the edge ring, and processing modules 460 as the plasma processing apparatus 1, which performs desired plasma processing on the substrate W transferred from the transfer module 450. A decompressed atmosphere is maintained inside the transfer module 450 and the processing modules 460, respectively. A plurality of, for example, six processing modules 460 are provided for one transfer module 450. The number and arrangement of the processing modules 460 are not limited to this.

In this embodiment, a storage container 464 is provided via a gate valve 465 on the side of the processing module 460 that does not face the transfer module 450. The storage container 464 may be provided in all of the processing modules 460, or may be provided in some of the processing modules 460. The transfer module 450 consists of a polygonal (pentagonal in the illustrated example) housing and is connected to the load lock modules 420 and 421 as described above. The transfer module 450 transfers the substrate W loaded into the load lock module 420 to one processing module 460 and unloads the substrate W plasma processed in the processing module 460 to the atmospheric part 410 via the load lock module 421.

The processing module 460 performs plasma processing such as etching, film formation, and diffusion on the substrate W using plasma. The processing module 460 is connected to the transfer module 450 via a gate valve 461. A transfer device 470 for transferring the substrate W and the edge ring is provided inside the transfer module 450. The transfer device 470 includes a transfer arm 471 as a support that moves while supporting the substrate W and the edge ring, a rotary table 472 that rotatably supports the transfer arm 471, and a base 473 on which the rotary table 472 is mounted. Further, a guide rail 474 extending in the longitudinal direction of the transfer module 450 is provided inside the transfer module 450. The base 473 is provided on the guide rail 474, and the transfer device 470 is configured to be movable along the guide rail 474. For example, the transfer arm AM of FIGS. 5A to 5E and 6A to 6E described above is the same as the transfer arm 471.

In the transfer module 450, the substrate W held in the load lock module 420 is received by the transfer arm 471 and loaded into the processing module 460. Further, the substrate W held in the processing module 460 is received by the transfer arm 471 and unloaded into the load lock module 421.

Further, the substrate processing system 400 includes a control device 480. In the embodiment, the control device 480 processes computer-executable instructions that cause the substrate processing system 400 to perform various processes described in the present disclosure. The control device 480 may be configured to control any of the other components of the substrate processing system 400 to perform various processes described herein. For example, the control device 480 may include a computer 490. The computer 490 may include, for example, a processing part 491, a storage part 492, and a communication interface 493. The processing part 491 may be configured to perform various control operations based on programs stored in the storage part 492. The communication interface 493 may communicate with other components of the substrate processing system 400 via a communication line, such as a local area network (LAN).

In the substrate processing system 400, the edge ring is stored in the storage container 464. The number and arrangement of storage containers 464 are not limited to those of this embodiment and can be arbitrarily. At least one storage container 464 may be provided. The interior of the storage container 464 is also maintained in a decompressed atmosphere, as are the interiors of the transfer module 450 and the processing module 460.

In the transfer module 450, the edge ring stored in the storage container 464 is received by the transfer arm 471 and transferred to the processing module 460 without passing through the transfer module 450. Further, in the transfer module 450, the edge ring held in the processing module 460 is received by the transfer arm 471 and transferred to the storage container 464 without passing through the transfer module 450. That is, the edge ring stored in the storage container 464 is accessed through the gate valve 461, the processing module 460, and the gate valve 465 by the transfer device 470 extending the transfer arm 471.

By arranging the storage container 464 adjacent to the processing module 460 and storing the edge ring in the storage container 464, the transfer time can be reduced and the throughput can be increased. Further, it is possible to eliminate the need for a storage container in the transfer module 450. Further, because the edge ring can be replaced without passing through the transfer module 450, it is possible to avoid bringing particles adhering to the edge ring into the transfer module 450. In the present disclosure, the storage container 462 is disposed adjacent to the transfer module 450. The storage container 462 may store consumable parts such as a cover ring other than the edge ring, a jig, and the like. Only one of the storage containers 462 and 464 may be provided.

The elevating part 50 can also be used for cleaning the inside of the plasma processing apparatus 1. For example, an unfixed edge ring to be transferred (for example, the inner edge ring 112a) can move up and down. Therefore, by raising, for example, the inner edge ring 112a to be transferred during cleaning, it is possible to clean between the inner edge ring 112a and the outer edge ring 112b and between these edge rings and the electrostatic chuck 1111. If the inner edge ring 112a is raised at a time other than cleaning, reaction products may accumulate between the inner edge ring 112a and the outer edge ring 112b. In this case, the reaction products can be removed by raising the inner edge ring 112a during cleaning. This cleaning method is effective even when the edge ring to be transferred is attached with reaction products, although it is not worn enough to be replaced.

As described above, according to the substrate processing apparatus, the method for aligning the ring member, and the transfer method of the present embodiment, it is possible to align the ring member with high accuracy when replacing the ring member in the substrate processing apparatus.

The substrate processing apparatus and the method for aligning the ring member according to the embodiments disclosed herein should be considered as examples and not restrictive in all respects. The embodiments can be modified and improved in various ways without departing from the scope and spirit of the appended claims. The elements described in the foregoing multiple embodiments can assume other configurations within a consistent range and can be combined within a consistent range.

The substrate processing apparatus disclosed herein is not limited to an apparatus that processes a substrate using plasma, and may be an apparatus that processes a substrate without using plasma.

The embodiments disclosed above include, for example, the following aspects.

### APPENDIX 1

A substrate processing apparatus comprising:
a plasma processing chamber;
a support accommodated in the plasma processing chamber;
an inner edge ring provided around a substrate;
an outer edge ring provided around the inner edge ring, the outer edge ring having an inner peripheral portion overlapping an outer peripheral portion of the inner edge ring when viewed from above and having a first alignment portion;
an outer edge ring electrostatic chuck disposed at a position of the support, the position facing the outer edge ring; and
a lifter configured to move the inner edge ring and/or the outer edge ring up and down,
wherein the inner edge ring is configured to be aligned with the outer edge ring by the first alignment portion in a state in which the outer edge ring electrostatic chuck is driven and the outer edge ring is attracted.

### APPENDIX 2

The substrate processing apparatus of appendix 1, wherein the lifter has a pin and an actuator that moves the pin up and down.

### APPENDIX 3

The substrate processing apparatus of appendix 1, wherein the first alignment portion includes a tapered surface formed on at least a portion of an inner peripheral surface of the outer edge ring.

### APPENDIX 4

The substrate processing apparatus of appendix 1, wherein the first alignment portion includes a protrusion and/or a recess formed on at least a portion of a surface overlapping the inner edge ring when viewed from above.

### APPENDIX 5

The substrate processing apparatus of appendix 3, wherein the inner edge ring has a second alignment portion, and
the inner edge ring and the outer edge ring are aligned by the first alignment portion and the second alignment portion.

### APPENDIX 6

The substrate processing apparatus of appendix 5, wherein the second alignment portion includes a tapered surface formed on at least a portion of an outer peripheral surface of the inner edge ring, and the inner edge ring and the outer edge ring are aligned by the tapered surface of the inner edge ring and the tapered surface of the outer edge ring.

### APPENDIX 7

The substrate processing apparatus of appendix 5, wherein the first alignment portion includes a protrusion and/or a recess formed on at least a portion of a surface overlapping the inner edge ring when viewed from above, the second alignment portion includes a protrusion and/or a recess formed on at least a portion of a surface overlapping the outer edge ring when viewed from above, and the inner edge ring and the outer edge ring are aligned by the protrusion of the inner edge ring and the recess of the outer edge ring or by the recess of the inner edge ring and the protrusion of the outer edge ring.

### APPENDIX 8

The substrate processing apparatus of appendix 1, wherein the outer edge ring electrostatic chuck is a bipolar electrostatic chuck.

### APPENDIX 9

The substrate processing apparatus of appendix 1, wherein the inner edge ring and the outer edge ring are arranged concentrically.

### APPENDIX 10

The substrate processing apparatus of appendix 1, wherein the inner edge ring and the outer edge ring are made of the same material.

### APPENDIX 11

The substrate processing apparatus of appendix 1, further comprising:
an inner edge ring electrostatic chuck disposed at a position facing the inner edge ring in the support.

### APPENDIX 12

The substrate processing apparatus of appendix 1, wherein the outer edge ring has a through hole penetrating through the outer edge ring in a thickness direction at a portion overlapping the inner edge ring when viewed from above, and
the lifter penetrates the through hole and moves up and down.

### APPENDIX 13

The substrate processing apparatus of appendix 1, further comprising:
a storage container disposed adjacent to the substrate processing apparatus and storing at least one of an inner edge ring for replacement and an outer edge ring for replacement.

### APPENDIX 14

The substrate processing apparatus of appendix 2, further comprising:
a gas supply for supplying a cleaning gas into the plasma processing chamber,
wherein the actuator drives the pin to move up and down in accordance with the supply of the cleaning gas, and
the pin is configured to raise the inner edge ring and/or the outer edge ring.

### APPENDIX 15

The substrate processing apparatus of appendix 2, further comprising:
a control device,
wherein the control device controls the actuator to:
raise and lower the pin to unload the inner edge ring from the plasma processing chamber;
raise the pin to hold an inner edge ring for replacement on the pin; and
lower the pin to align the inner edge ring for replacement by the first alignment portion provided on the outer edge ring.

### APPENDIX 16

The substrate processing apparatus of appendix 2, further comprising:
a control device,
wherein the control device controls the actuator to:
raise and lower the pin to unload the outer edge ring from the plasma processing chamber;
raise the pin to hold an outer edge ring for replacement on the pin; and
lower the pin to align the outer edge ring for replacement by the first alignment portion provided on the outer edge ring for replacement.

### APPENDIX 17

The substrate processing apparatus of appendix 2, further comprising:
a control device,
wherein the control device controls the actuator to:
raise and lower the pin to unload the inner edge ring and the outer edge ring from the plasma processing chamber;
raise the pin to hold an inner edge ring for replacement and an outer edge ring for replacement on the pin; and
lower the pin to align the inner edge ring for replacement and the outer edge ring for replacement by the first alignment portion provided on the outer edge ring for replacement.

### APPENDIX 18

A method for aligning a ring member performed by the substrate processing apparatus described in claim 2, the method comprising:
unloading the inner edge ring from the plasma processing chamber by raising and lowering the pin using the actuator;
holding an inner edge ring for replacement on the pin by raising the pin using the actuator; and
aligning the inner edge ring for replacement by the first alignment portion provided on the outer edge ring by lowering the pin using the actuator.

### APPENDIX 19

A method for aligning a ring member performed by the substrate processing apparatus described in claim 2, the method comprising:
unloading the outer edge ring from the plasma processing chamber by raising and lowering the pin using the actuator;
holding an outer edge ring for replacement on the pin by raising the pin using the actuator; and
aligning the outer edge ring for replacement by the first alignment portion provided on the outer edge ring by lowering the pin using the actuator.

### APPENDIX 20

A method for aligning a ring member performed by the substrate processing apparatus described in claim 2, the method comprising:
unloading the inner edge ring and the outer edge ring from the plasma processing chamber by raising and lowering the pin using the actuator;
holding an inner edge ring for replacement and an outer edge ring for replacement on the pin by raising the pin using the actuator; and
aligning the inner edge ring for replacement and the outer edge ring for replacement by the first alignment portion provided on the outer edge ring by lowering the pin using the actuator.

While certain embodiments have been described, these embodiments have been presented by way of example only and are not intended to limit the scope of the disclosure. In fact, the embodiments described herein may be embodied in a variety of other forms. Furthermore, various omissions, substitutions, and changes in the form of the embodiments described herein may be made without departing from the spirit of the disclosure. The accompanying claims and their equivalents are intended to cover such forms or modifications as would fall within the scope and spirit of the disclosure.

1. A substrate processing apparatus comprising:
a plasma processing chamber;
a support accommodated in the plasma processing chamber;
an inner edge ring provided around a substrate;
an outer edge ring provided around the inner edge ring, the outer edge ring having an inner peripheral portion overlapping an outer peripheral portion of the inner edge ring when viewed from above and having a first alignment portion;
an outer edge ring electrostatic chuck disposed at a position of the support, the position facing the outer edge ring; and
a lifter configured to move the inner edge ring and/or the outer edge ring up and down,
wherein the inner edge ring is configured to be aligned with the outer edge ring by the first alignment portion in a state in which the outer edge ring electrostatic chuck is driven and the outer edge ring is attracted.

2. The substrate processing apparatus of claim 1, wherein the lifter has a pin and an actuator that moves the pin up and down.

3. The substrate processing apparatus of claim 1, wherein the first alignment portion includes a tapered surface formed on at least a portion of an inner peripheral surface of the outer edge ring.

4. The substrate processing apparatus of claim 1, wherein the first alignment portion includes a protrusion and/or a recess formed on at least a portion of a surface overlapping the inner edge ring when viewed from above.

5. The substrate processing apparatus of claim 3, wherein the inner edge ring has a second alignment portion, and
the inner edge ring and the outer edge ring are aligned by the first alignment portion and the second alignment portion.

6. The substrate processing apparatus of claim 5, wherein the second alignment portion includes a tapered surface formed on at least a portion of an outer peripheral surface of the inner edge ring, and the inner edge ring and the outer edge ring are aligned by the tapered surface of the inner edge ring and the tapered surface of the outer edge ring.

7. The substrate processing apparatus of claim 5, wherein the first alignment portion includes a protrusion and/or a recess formed on at least a portion of a surface overlapping the inner edge ring when viewed from above, the second alignment portion includes a protrusion and/or a recess formed on at least a portion of a surface overlapping the outer edge ring when viewed from above, and the inner edge ring and the outer edge ring are aligned by the protrusion of the inner edge ring and the recess of the outer edge ring or by the recess of the inner edge ring and the protrusion of the outer edge ring.

8. The substrate processing apparatus of claim 1, wherein the outer edge ring electrostatic chuck is a bipolar electrostatic chuck.

9. The substrate processing apparatus of claim 1, wherein the inner edge ring and the outer edge ring are arranged concentrically.

10. The substrate processing apparatus of claim 1, wherein the inner edge ring and the outer edge ring are made of the same material.

11. The substrate processing apparatus of claim 1, further comprising:
an inner edge ring electrostatic chuck disposed at a position facing the inner edge ring in the support.

12. The substrate processing apparatus of claim 1, wherein the outer edge ring has a through hole penetrating through the outer edge ring in a thickness direction at a portion overlapping the inner edge ring when viewed from above, and
the lifter penetrates the through hole and moves up and down.

13. The substrate processing apparatus of claim 1, further comprising:
a storage container disposed adjacent to the substrate processing apparatus and storing at least one of an inner edge ring for replacement and an outer edge ring for replacement.

14. The substrate processing apparatus of claim 2, further comprising:
a gas supply for supplying a cleaning gas into the plasma processing chamber,
wherein the actuator drives the pin to move up and down in accordance with the supply of the cleaning gas, and
the pin is configured to raise the inner edge ring and/or the outer edge ring.

15. The substrate processing apparatus of claim 2, further comprising:
a control device,
wherein the control device controls to:
unload the inner edge ring from the plasma processing chamber by raising and lowering the pin using the actuator;
hold an inner edge ring for replacement on the pin by raising the pin using the actuator; and
align the inner edge ring for replacement by the first alignment portion provided on the outer edge ring by lowering the pin using the actuator.

16. The substrate processing apparatus of claim 2, further comprising:
a control device,
wherein the control device controls to:
unload the outer edge ring from the plasma processing chamber by raising and lowering the pin using the actuator;
hold an outer edge ring for replacement on the pin by raising the pin using the actuator; and
align the outer edge ring for replacement by the first alignment portion provided on the outer edge ring for replacement by lowering the pin using the actuator.

17. The substrate processing apparatus of claim 2, further comprising:
a control device,
wherein the control device controls to:
unload the inner edge ring and the outer edge ring from the plasma processing chamber by raising and lowering the pin using the actuator;
hold an inner edge ring for replacement and an outer edge ring for replacement on the pin by raising the pin using the actuator; and
align the inner edge ring for replacement and the outer edge ring for replacement by the first alignment portion provided on the outer edge ring for replacement by lowering the pin using the actuator.

18. A method for aligning a ring member performed by the substrate processing apparatus described in claim 2, the method comprising:
unloading the inner edge ring from the plasma processing chamber by raising and lowering the pin using the actuator;
holding an inner edge ring for replacement on the pin by raising the pin using the actuator; and
aligning the inner edge ring for replacement by the first alignment portion provided on the outer edge ring by lowering the pin using the actuator.

19. A method for aligning a ring member performed by the substrate processing apparatus described in claim 2, the method comprising:
unloading the outer edge ring from the plasma processing chamber by raising and lowering the pin using the actuator;
holding an outer edge ring for replacement on the pin by raising the pin using the actuator; and
aligning the outer edge ring for replacement by the first alignment portion provided on the outer edge ring for replacement by lowering the pin using the actuator.

20. A method for aligning a ring member performed by the substrate processing apparatus described in claim 2, the method comprising:
unloading the inner edge ring and the outer edge ring from the plasma processing chamber by raising and lowering the pin using the actuator;
holding an inner edge ring for replacement and an outer edge ring for replacement on the pin by raising the pin using the actuator; and
aligning the inner edge ring for replacement and the outer edge ring for replacement by the first alignment portion provided on the outer edge ring for replacement by lowering the pin using the actuator.
